(19) United States
(12) Patent Application Publication
(10) Pub. No.: US 2024/0211420 A1
(43) Pub. Date: Jun. 27, 2024

(54) QUAD-CHANNEL MEMORY MODULE

(71) Applicant: Rambus Inc., San Jose, CA (US)

(72) Inventors: Steven C. WOO, Saratoga, CA (US); Dongyun LEE, Sunnyvale, CA (US)

(21) Appl. No.: 18/569,451

(22) PCT Filed: Jun. 20, 2022
(86) PCT No.: PCT/US22/34142

§ 371 Date: Dec. 12, 2023

Related U.S. Application Data
(60) Provisional application No. 63/213,337, filed on Jun. 22, 2021.
(60) Provisional application No. 63/246,664, filed on Sep. 21, 2021.

(51) Int. Cl. G06F 13/16

(52) U.S. Cl. CPC G06F 13/1673; G06F 13/1689

(57) ABSTRACT

A four-channel memory module includes four independent memory channels and dual channel memory devices. The channels of the dual channel memory are accessed independently. Thus, the four channels for accessing the memory module each access one channel of a first set and a second set of dual channel memory devices on the module. Dual channel data buffer devices are also included on the module. The dual channel data buffer devices also retime data strobe signals for accesses to/from the sets of dual channel memory devices.

### BRIEF DESCRIPTION OF THE DRAWINGS

FIG. 1 is a block diagram illustrating a memory system.

FIGS. 2A-2C illustrate a buffered memory module.

FIG. 3 illustrates example data buffer circuitry.

FIG. 4 is a timing diagram illustrating a read operation.

FIG. 5 is a timing diagram illustrating a write operation

FIG. 6 is a timing diagram illustrating read operations communicated using two level and four level pulse amplitude modulation.

FIG. 7 is a flowchart illustrating a method of accessing a dual channel memory device.

FIG. 8 is a flowchart illustrating a method of providing a data strobe to a controller.

FIG. 9 is a flowchart illustrating a method of providing data strobes to memory devices.

FIG. 10 is a block diagram of a processing system.

### DETAILED DESCRIPTION OF THE EMBODIMENTS

A four-channel memory module includes four independent memory channels and dual channel memory devices. The channels of the dual channel memory are accessed independently. Thus, the four channels for accessing the memory module each access one channel of a first set and a second set of dual channel memory devices on the module. Dual channel data buffer devices are also included on the module. The dual channel data buffer devices also retime data strobe signals for accesses to/from the sets of dual channel memory devices.

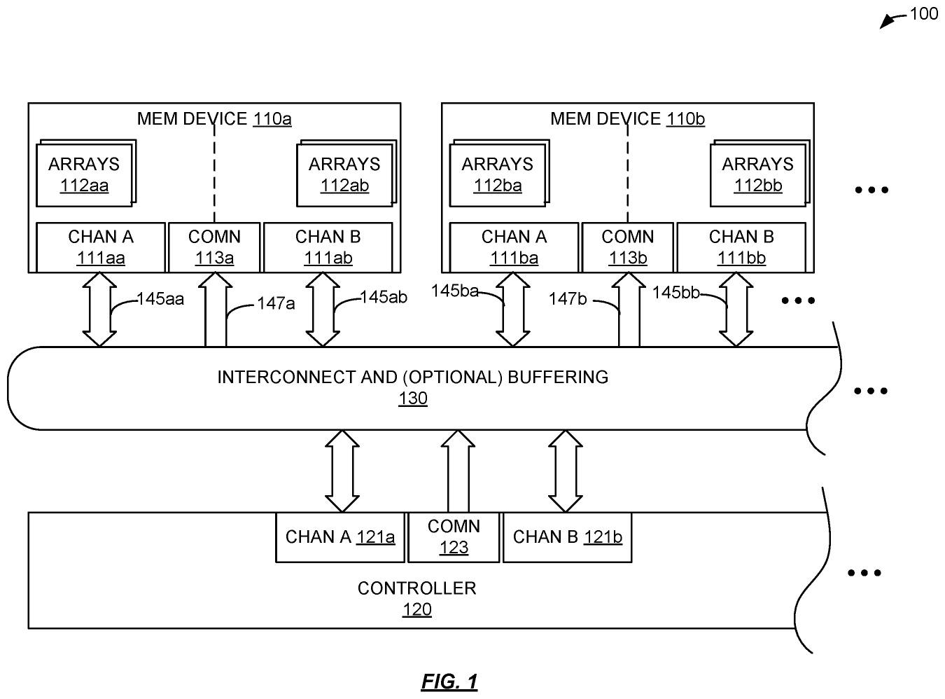

FIG. 1 is a block diagram illustrating a memory system. In FIG. 1 memory system 100 comprises memory devices 110a-110b, controller 120, and interconnect 130. Interconnect 130 may optionally include buffering. Memory devices 110a-110b respectively include channel A interface 111aa-111ba, channel B interface 111ab-111bb, and common signal interface 113a-113b. Memory device 110a also includes memory arrays 112aa-112ab. Memory device 110b includes memory arrays 112ba-112bb. Controller 120 includes channel A interface 121a, channel B interface 121b, and common signal interface 123. In an embodiment, memory devices 110a-110b are disposed on a substrate having local interfaces (not shown in FIG. 1), local interconnects 145aa-145bb, and 147a-147b thereby forming a memory module.

Controller 120 is operatively coupled to channel A interface 111aa of memory device 110a via channel A interface 121a, interconnect 130, and local interconnect 145aa. Controller 120 is operatively coupled to channel B interface 111ab of memory device 110a via channel B interface 121b, interconnect 130, and local interconnect 145ab. Controller 120 is operatively coupled to common signal interface (e.g., clock signal, chip select) 113a of memory device 110a via common signal interface 123, interconnect 130, and local interconnect 147a.

Controller 120 is operatively coupled to channel A interface 111ba of memory device 110b via channel A interface 121a, interconnect 130, and local interconnect 145ba. Controller 120 is operatively coupled to channel B interface 111bb of memory device 110b via channel B interface 121b, interconnect 130, and local interconnect 145bb. Controller 120 is operatively coupled to common signal interface 113b of memory device 110b via common signal interface 123, interconnect 130, and local interconnect 147b.

Each of channels A-B of memory devices 110a-110b operate command, address, and data transfer functions of their respective channels A-B and channel interfaces 111aa-111bb independently of the other channel A-B and channel interfaces 111aa-111bb. Each of channels A-B access non-overlapping sets of memory arrays 112aa-112bb in their respective memory device 110a-110b. In an embodiment, each of channel interfaces 111aa-111bb and 121a-121b include two (2) bidirectional data (DQ) signals and at least one data strobe (DQS) signal. Each of the channel interfaces 111aa-111bb 121a-121b include a command address (CA) bus interface that operates independently of the other CA bus interfaces to access non-overlapping sets of memory arrays 112aa-112bb in their respective memory device 110a-110b.

In an embodiment, memory device 110a-110b are representative of a larger number of memory devices 110a-110b on a memory module. For example, memory devices 110a-110b may be representative of ten (10) memory devices 110a-110b on a memory module. In this example, therefore, channel interfaces 121a-121b of controller 120 form two (A and B) twenty (20) data bit channels (along with accompanying CA signals). Each twenty data bit channel may communicate sixteen (16) data bits along with four (4) bits of reliability, availability, serviceability (RAS) information (e.g., Reed-Solomon—RS—coding or error correct and detect EDC coding).

Controller 120 may also include additional channels coupled to additional memory devices 110a-110b on the same module. For example, controller 120 may include two additional channel interfaces (e.g., channel C and channel D interfaces) that couple to another ten (10) memory devices thereby forming an additional two (C and D) twenty (20) data bit channels (along with accompanying CA signals). Similar to channels A-B, each additional twenty data bit channel may communicate sixteen (16) data bits along with four (4) bits of RAS information.

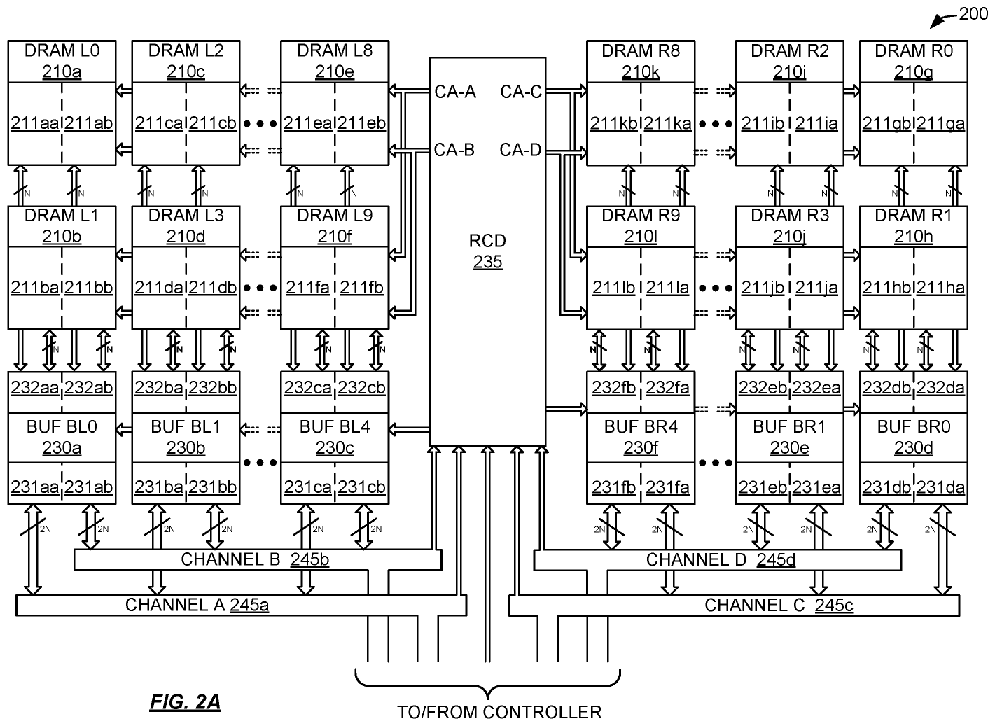

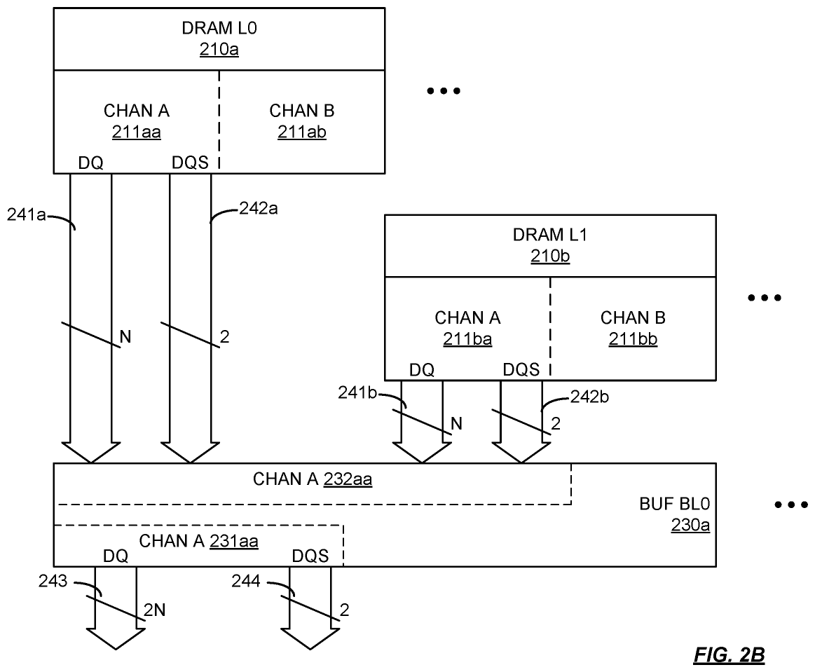

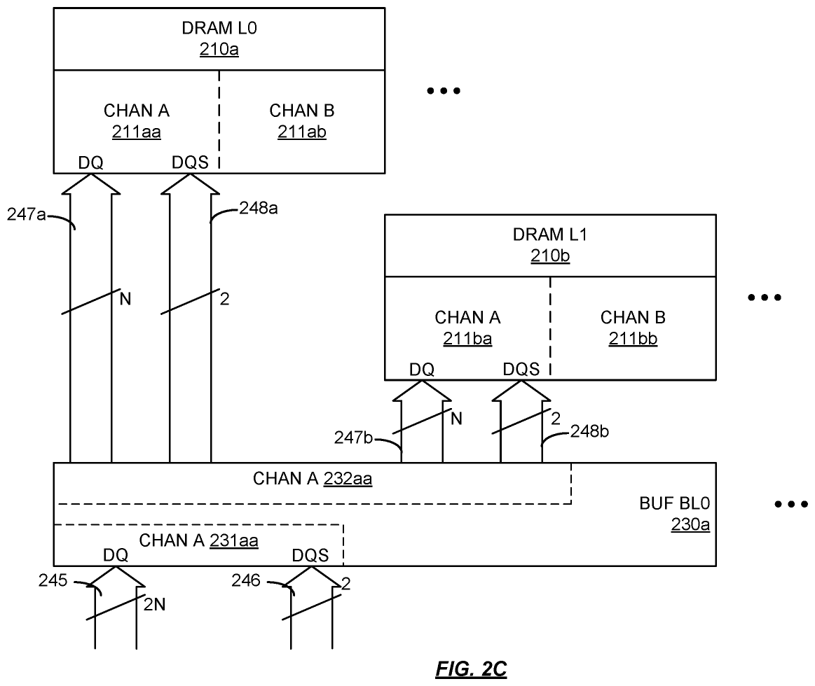

FIGS. 2A-2C illustrate a buffered memory module. In FIG. 2A, module 200 comprises left side dual channel DRAM devices 210a-210f (representing ten DRAM devices L0-L9), right side dual channel DRAM devices 210g-2101 (representing ten DRAM devices R0-R9), left side dual channel buffer devices 230a-230c (representing five buffer devices BL0-BL4), right side dual channel buffer devices 230d-230f (representing five buffer devices BR0-BR4), registering clock driver (RCD) 235, channel A interface 245a, channel B interface 245b, channel C interface 245c, and channel D interface 245d. RCD 235 receives certain signals (e.g., clock, chip select) that are common to the channel A-D interfaces 245a-245d.

Each dual channel DRAM device 210a-2101 includes two non-overlapping set of memory arrays that are respectively accessed via two channel interfaces 211aa-2111b that operate independently of each other. In other words, each DRAM device 210a-2101 device operates the command, address, and data transfer functions of their respective channel interfaces 211aa-2111b independently of the other channel interfaces 211aa-211lb on the same DRAM device 210a-2101. Thus, for example, channel A interface 211aa of DRAM L0 210a accesses a first set of memory arrays in DRAM L0 210a and channel B interface 211ab of DRAM L0 210a accesses a second set of memory arrays in DRAM L0 210a, where the first set of memory arrays and the second set of memory array do not have any common memory array (i.e., are non-overlapping sets).

At least the CA signals of channel A interface 245a are operatively coupled to RCD 235. RCD 235 operatively couples the CA signals of channel A interface 245a to the channel A interfaces 211aa-211fa of the left side DRAM devices 210a-210f. Similarly, at least the CA signals of channel B interface 245b are operatively coupled to RCD 235. RCD 235 operatively couples the CA signals of channel B interface 245b to the channel B interfaces 211ab-211fb of the left side DRAM devices 210a-210f.

At least the CA signals of channel C interface 245c are operatively coupled to RCD 235. RCD 235 operatively couples the CA signals of channel C interface 245c to the channel A interfaces 211ga-211la of the right side DRAM devices 210g-2101. Similarly, at least the CA signals of channel D interface 245d are operatively coupled to RCD 235. RCD 235 operatively couples the CA signals of channel D interface 245d to the channel B interfaces 211gb-2111b of the right side DRAM devices 210g-2101.

The channel A interface 211aa of DRAM device 210a is operatively coupled to communicate N bits of data with the device side channel A interface 232aa of data buffer device 230a. In an embodiment, N=2. The channel B interface 211ab of DRAM device 210a is operatively coupled to communicate N bits of data with the device side channel B interface 232ab of data buffer device 230a. The channel A interface 211ba of DRAM device 210b is operatively coupled to communicate N bits of data with the device side channel A interface 232aa of data buffer device 230a; the channel B interface 211bb of DRAM device 210b is operatively coupled to communicate N bits of data with the device side channel B interface 232ab of data buffer device 230a; the channel A interface 211ca of DRAM device 210c is operatively coupled to communicate N bits of data with the device side channel A interface 232ba of data buffer device 230b; the channel B interface 211cb of DRAM device 210c is operatively coupled to communicate N bits of data with the device side channel B interface 232bb of data buffer device 230a, and so on with a like pattern of connection for all of the DRAM devices 210a-2101 and data buffer devices 230a-230f on module 200 (which, for the sake of brevity will not be detailed herein).

Controller side channel A interface 231aa is operatively coupled to channel A interface 245a. Controller side channel A interface 231aa communicates 2*N bits with channel A interface 245a. The 2*N bits comprise N bits communicated with DRAM device 210a and N bits communicated with DRAM device 210b for a total of 2*N number of bits. Similarly, controller side channel B interface 231ab is operatively coupled to channel B interface 245b. Likewise, the controller side channel A interfaces 231ba-231ca of data buffer devices 230b-230c are operatively coupled to channel A interface 245a; the controller side channel B interfaces 231bb-231cb of data buffer devices 230b-230c are operatively coupled to channel B interface 245b; the controller side channel C interfaces 231da-231fa of data buffer devices 230d-230f are operatively coupled to channel C interface 245c; and, the controller side channel D interfaces 231db-231fb of data buffer devices 230d-230f are operatively coupled to channel D interface 245d.

FIG. 2B illustrates a read operation on channel A of module 200 using DRAM devices 210a-210b and data buffer device 230a as a representative example. In FIG. 2B, channel A interface 211aa of DRAM device 210a provides N bits of data signals 241a and a differential data strobe (DQS) signal 242a to device side channel A interface 232aa of data buffer device 230a. Channel A interface 211ba of DRAM device 210b provides N bits of data signals 241b and a differential data strobe (DQS) signal 242b to device side channel A interface 232aa of data buffer device 230a. In response, data buffer device 230a realigns (re-times) one or more of data signals 241a-241b to be output by controller side channel A interface 231aa as 2N number of data signals 243 in relation to a data strobe signal 244 also output by controller side channel A interface 231aa. It should be understood that since the timing of data signals 243 is in relation to the timing of data strobe signal 244, data buffer device 230a may equivalently be seen as realigning (re-timing) one or more of data strobe signals 242a-242b in relation to received data signals 241a-241b before being output by controller side channel A interface 231aa as 2N number of data signals 243 in relation to a data strobe signal 244. It should also be understood that re-timing the data signals 243 being output by data buffer device 230a in relation to a single differential data strobe signal 244 rather than two differential data strobe signals 242a-242b reduces the number of data strobes being sent by controller side channel interfaces 231aa-231fb of data buffer devices 230a-230f to a controller.

FIG. 2C illustrates a write operation on channel A of module 200 using DRAM devices 210a-210b and data buffer device 230a as a representative example. In FIG. 2C, controller side channel A interface 231aa of data buffer device 230a receives 2N bits of data signals 245 and a differential data strobe (DQS) signal 246 from a controller. In response, data buffer device 230a realigns (re-times) data signals 247a in relation to a data strobe signal 248a output by device side channel A interface 232aa. Similarly, data buffer device 230a realigns (re-times) data signals 247b in relation to a data strobe signal 248b output by device side channel A interface 232aa. Channel A interface 232aa of data buffer device 230a provides N bits of data signals 247a and a differential data strobe (DQS) signal 248a to channel A interface 211aa of DRAM device 210a. Channel A interface 232aa of data buffer device 230a provides N bits of data signals 247b and a differential data strobe (DQS) signal 248b to channel A interface 211ba of DRAM device 210b. It should be understood that since the timing of data signals 247a-247b is in relation to the timing of data strobe signals 248a-248b, data buffer device 230a may equivalently be seen as realigning (re-timing) data strobe signal 246 in relation to received data signals 245 before being output by device side channel A interface 232aa as two sets of N number of data signals 247a-247b in relation to respective data strobe signals 248a-248b. It should also be understood that re-timing the data signals 247a-247b being output by data buffer device 230a in relation to two data strobe signals 248a-248b reduces the number of data strobes being sent by the controller to data buffer devices 230a-230f.

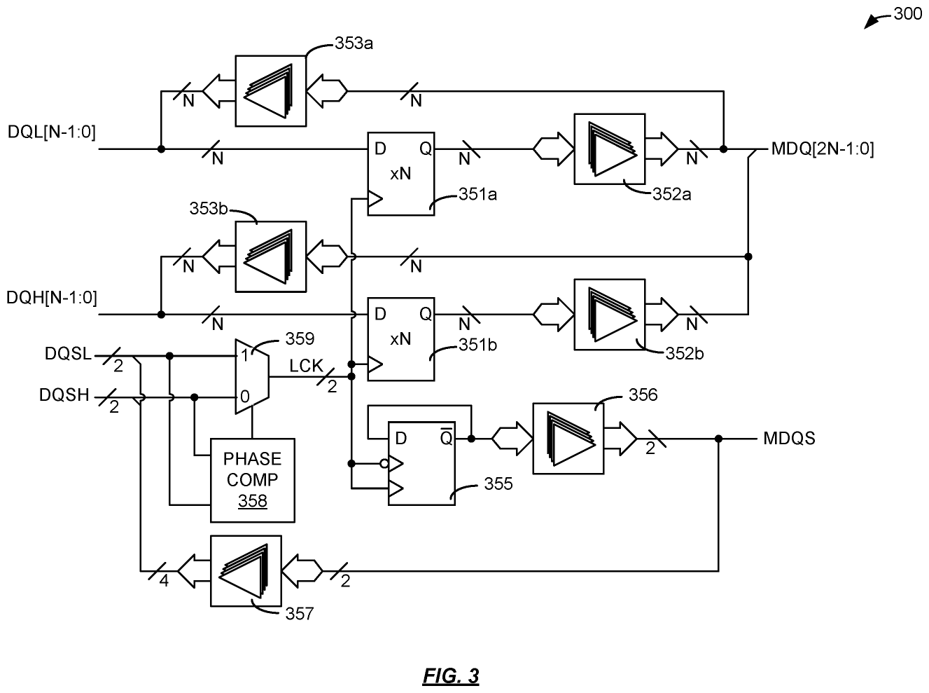

FIG. 3 illustrates example data buffer circuitry. The circuitry illustrated in FIG. 3 may be included in and/or used by data buffer devices 230a-230f. All or part of the circuitry illustrated in FIG. 3 may be, or be part of, for example, device side interfaces 232aa-232fb and/or controller side channel interfaces 231aa-231fb. Data buffer circuitry 300 comprises N number of device side least significant bits (LSB) latches 351a, N number of device side most significant bits (MSB) latches 351b, N number of controller side LSB buffers 352a, N number of controller side MSB buffers 352b, N number of device side LSB buffers 353a, N number of device side MSB buffers 353b, toggle latch 355, controller side read data strobe buffers 356, device side write data strobe buffers 357, phase comparator 358, and 2:1 multiplexor (MUX) 359.

For read operations, LSB latches 351a receive N number of LSB bits DQL[N-1:0] from a first DRAM device and latch the values upon the transition of LCK. Likewise, for read operations, MSB latches 351b receive N number of MSB bits DQH[N-1:0] from a second DRAM device and latch the values upon the transition of LCK. The outputs of LSB latches 351a and MSB latches 351b are respectively buffered by controller side LSB buffers 352a and controller side MSB buffers 352b. The outputs of controller side LSB buffers 352a and controller side MSB buffers 352b are provided to the controller (e.g., by controller side channel interface 231 aa-231fb) as read data signals.

Phase comparator 358 receives a data strobe DQSL from the first DRAM device and a data strobe DQSH from the second DRAM device. Phase comparator 358 detects which of DQSL and DQSH arrives later and controls MUX 359 to select the later arriving data strobe signal to be output by MUX 359 as LCK. LCK is also provided to the clock inputs of toggle latch 355. Note that toggle latch 355 is activated by both rising and falling edge of LCK. Accordingly, in FIG. 3, the symbol for toggle latch 355 has two clock inputs one denoting active high and one denoted as active low. When LCK causes latches 351a-351b to latch DQL[N-1:0] and DQH[N-1:0], toggle latch 355 generates a transition in response. The transition by toggle latch 355 is buffered by read data strobe buffers 356. The output of read data strobe buffers 356 is provided to the controller (e.g., by controller side channel interface 231aa-231fb) as a read data strobe signal MDQS. It should be understood that latching DQL[N-1:0] and DQH[N-1:0] with their respective data strobe signals DQSL and DQSH, and selecting the later arriving strobe signal among DQSL or DQSH as the basis for the read data strobe signal MDQS provided to the controller retimes (realigns) the read data strobe signal(s) received by data buffer circuitry 300 relative to the controller side read data signals MDQ[2N-1:0] provided to the controller.

For write operations, device side LSB buffers 353a receive N number of LSB data signals MDQ[N-1:0] from the controller and provide those bits to the first DRAM device as write data signals DQL[N-1:0]. Similarly, device side MSB buffers 353b receive N number of MSB data signals MDQ[2N-1:N] from the controller and provide those bits to the second DRAM device as write data signals DQH[N-1:0]. A write data strobe signal MDQS received from the controller is provided to write data strobe buffers 357. Write data strobe buffers 357 output two device side write data strobe signals DQSL and DQSH that are provided to the first DRAM device and the second DRAM device, respectively. It should be understood that write data strobe buffers 357 may be trained or otherwise configured to provide DQSL and DQSH to the first DRAM device and the second DRAM device with different timing. In other words, write data strobe buffers 357 may individually re-time MDQS when producing DQSL and DQSH in order to account for different signal delays and/or timing requirements of the first DRAM device and the second DRAM device.

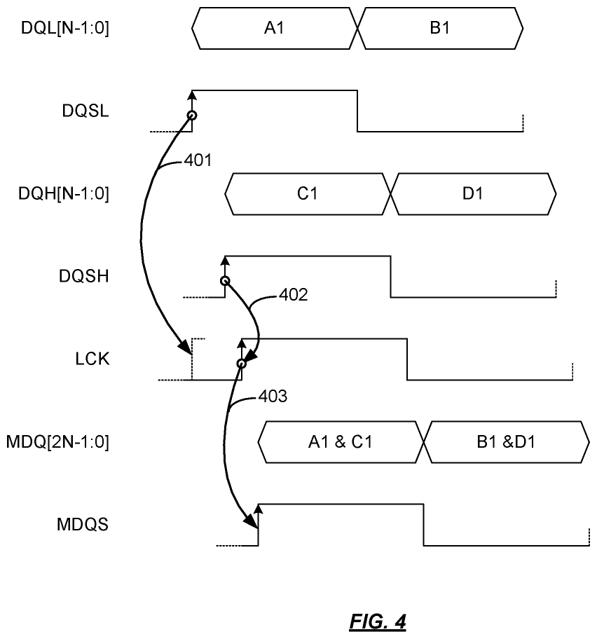

FIG. 4 is a timing diagram illustrating a read operation. The relative timings illustrated in FIG. 4 may be produced by, for example, data buffer circuitry 300. In FIG. 4, transitions on LSB data signals DQL[N-1:0] arrive coincident with transitions on LSB data strobe signal DQSL. After a rising edge on DQSL arrives, transitions on MSB data signals DQH[N-1:0] arrive coincident with a rising edge transition on MSB data strobe signal DQSH. Because the transition on DQSH arrived later than the corresponding transition on DQSL, DQSH is selected as the basis for LCK and therefore the controller read data strobe signal MDQS. This is illustrated in FIG. 4 by arrow 401 running from the rising edge transition on DQSL to a non-existent transition on LCK, arrow 402 running from the rising edge transition on DQSH to the rising edge transition on LCK, and arrow 403 running from the rising edge transition of LCK to the rising edge transition of MDQS.

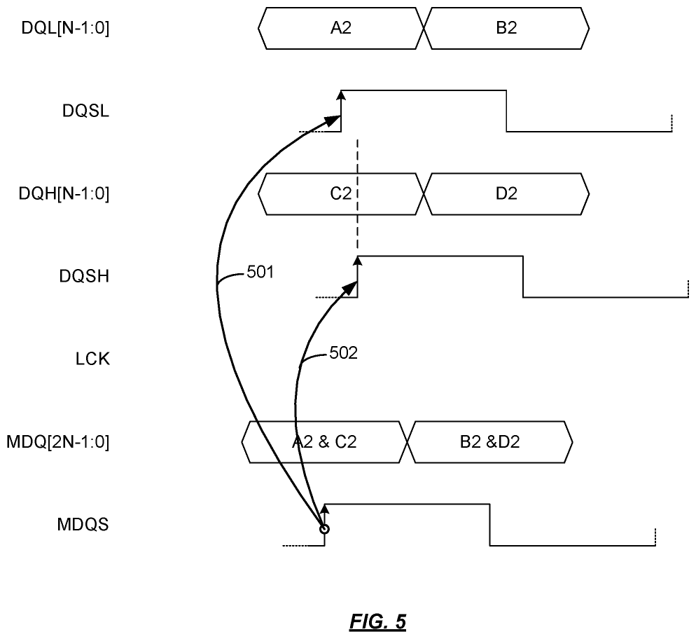

FIG. 5 is a timing diagram illustrating a write operation. The relative timings illustrated in FIG. 5 may be produced by, for example, data buffer circuitry 300. In FIG. 5, transitions on controller side write data signals MDQ[2N-1:0] arrive to be latched by transitions on controller side write data strobe signal MDQS. Based on write data strobe signal MDQS, LSB and MSB write data strobes DQSL and DQSH are produced with different timings (e.g., by write data strobe buffers 357). This is illustrated in FIG. 5 by arrow 501 running from the rising edge of MDQS to the rising edge of DQSL and arrow 502 running from the rising edge of MDQS to the rising edge of DQSH where the rising edges of DQSL and DQSH are not aligned in time. In an embodiment, the timing difference between rising edges of DQSH and DQSL can be programmed to compensate the nonidentical DQS tree timing drift in each device.

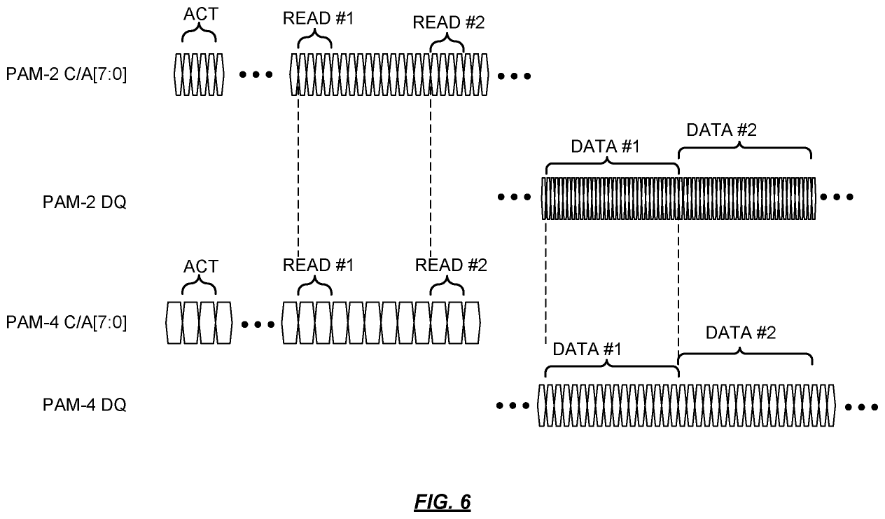

FIG. 6 is a timing diagram illustrating read operations communicated using two level and four level pulse amplitude modulation. In FIG. 6, the two level pulse amplitude modulation (PAM-2) and the four level pulse amplitude modulation (PAM-4) have the same packet timings, packet lengths (in time), and same access delays. To accomplish this, as is illustrated by FIG. 6, the PAM-2 command/address and data symbols are communicated at a rate that is twice the symbol rate of the PAM-4 symbol rate. Other timings (e.g., ACT to read, etc.) may be the same regardless of whether PAM-2 or PAM-4 signaling is used.

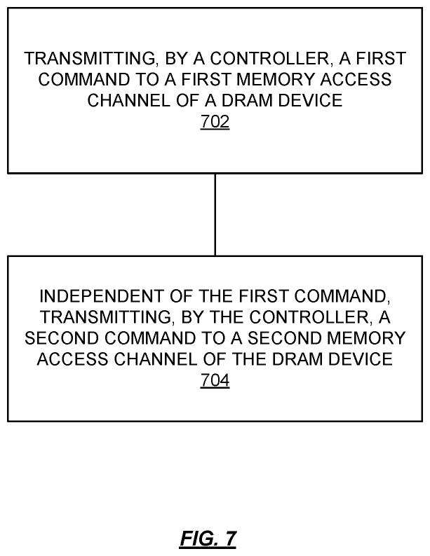

FIG. 7 is a flowchart illustrating a method of accessing a dual channel memory device. One or more of the steps illustrated in FIG. 7 may be performed by, for example, memory system 100, module 200, data buffer circuitry 300, and/or their components. By a controller, a first command is transmitted to a first memory access channel of a DRAM device (702). For example, controller 120 may transmit, via channel A interface 121a and channel A interfaces 111aa-111ba, a first memory access command.

Independent of the first command, a second command is transmitted to a second memory access channel of the DRAM device (704). For example, without regard to the existence and/or timing of the first command, controller 120 may transmit, via channel B interface 121b and channel B interfaces 111ab-111bb, a second memory access command.

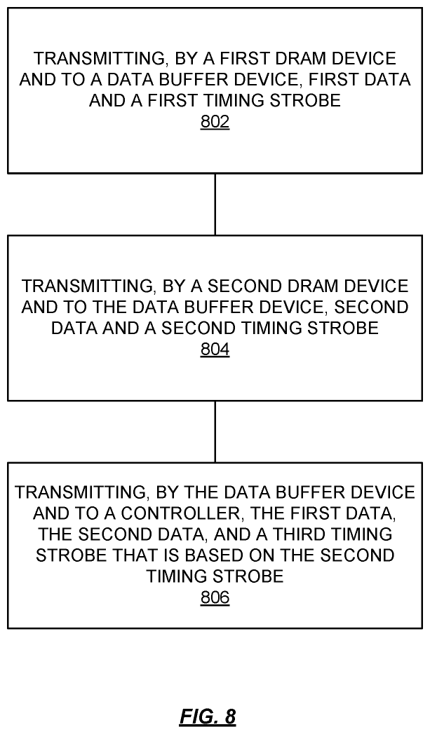

FIG. 8 is a flowchart illustrating a method of providing a data strobe to a controller. One or more of the steps illustrated in FIG. 8 may be performed by, for example, memory system 100, module 200, data buffer circuitry 300, and/or their components. By a first DRAM device and to a data buffer device, first data and a first data strobe are transmitted (802). For example, data signals 241a and data strobe signal 242a may be transmitted by DRAM device 210a to data buffer device 230a via channel A interface 211aa and device side channel A interface 232aa.

By a second DRAM device and to the data buffer device, second data and a second data strobe are transmitted (804). For example, data signals 241b and data strobe signal 242b may be transmitted by DRAM device 210b to data buffer device 230a via channel A interface 211ba and device side channel A interface 232aa. By the data buffer device and to a controller, the first data, the second data, and a third timing strobe that is based on the second timing strobe is transmitted (806). For example, data signals 243 and data strobe signal 244 may be transmitted by data buffer device 230a to a controller. Data strobe signal 244 may be based on data strobe signal 242b because data strobe signal 242b arrived later than data strobe signal 242a.

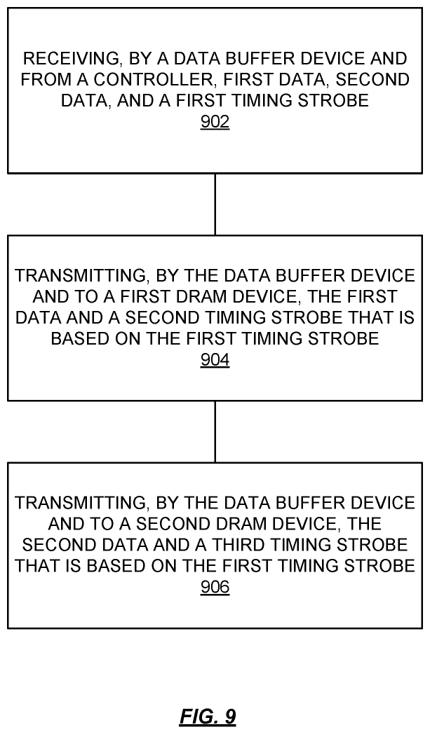

FIG. 9 is a flowchart illustrating a method of providing data strobes to memory devices. One or more of the steps illustrated in FIG. 9 may be performed by, for example, memory system 100, module 200, data buffer circuitry 300, and/or their components. By a data buffer and from a controller, first data, second data, and a first timing strobe are received (902). For example, data signals 245, comprising data to be relayed as data signals 247a and data signals 247b, and data strobe signal 246 may be received by data buffer device 230a from a controller.

By the data buffer device and to a first DRAM device, the first data, and a second timing strobe that is based on the first timing strobe, is transmitted. For example, data signals 247a and data strobe signal 248a may be transmitted by data buffer device 230a to DRAM device 210a where data strobe signal 248a is based on data strobe signal 246. By the data buffer device and to a second DRAM device, the second data, and a third timing strobe that is based on the first timing strobe, is transmitted. For example, data signals 247b and data strobe signal 248b may be transmitted by data buffer device 230a to DRAM device 210b where data strobe signal 248b is based on data strobe signal 246.

The methods, systems and devices described above may be implemented in computer systems, or stored by computer systems. The methods described above may also be stored on a non-transitory computer readable medium. Devices, circuits, and systems described herein may be implemented using computer-aided design tools available in the art, and embodied by computer-readable files containing software descriptions of such circuits. This includes, but is not limited to one or more elements of memory system 100, module 200, data buffer circuitry 300, and their components. These software descriptions may be: behavioral, register transfer, logic component, transistor, and layout geometry-level descriptions. Moreover, the software descriptions may be stored on storage media or communicated by carrier waves.

Data formats in which such descriptions may be implemented include, but are not limited to: formats supporting behavioral languages like C, formats supporting register transfer level (RTL) languages like Verilog and VHDL, formats supporting geometry description languages (such as GDSII, GDSIII, GDSIV, CIF, and MEBES), and other suitable formats and languages. Moreover, data transfers of such files on machine-readable media may be done electronically over the diverse media on the Internet or, for example, via email. Note that physical files may be implemented on machine-readable media such as: 4 mm magnetic tape, 8 mm magnetic tape, 3½ inch floppy media, CDs, DVDs, and so on.

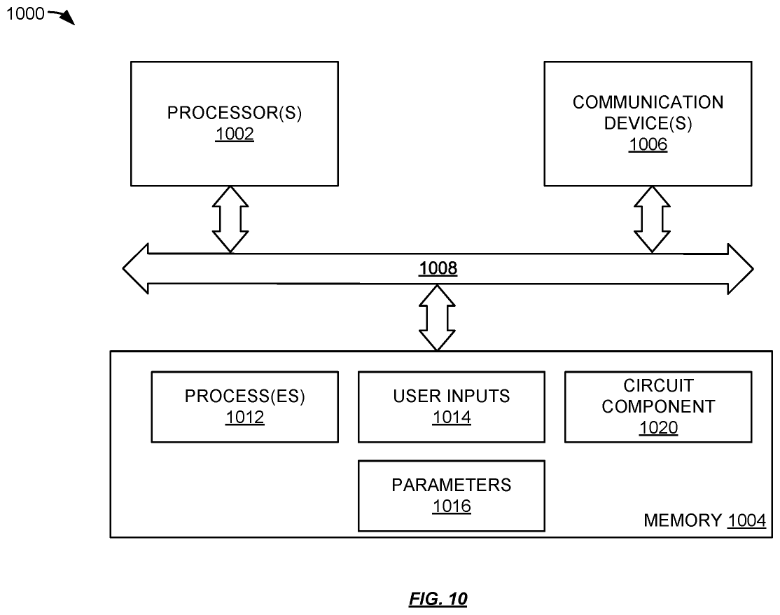

FIG. 10 is a block diagram illustrating one embodiment of a processing system 1000 for including, processing, or generating, a representation of a circuit component 1020. Processing system 1000 includes one or more processors 1002, a memory 1004, and one or more communications devices 1006. Processors 1002, memory 1004, and communications devices 1006 communicate using any suitable type, number, and/or configuration of wired and/or wireless connections 1008.

Processors 1002 execute instructions of one or more processes 1012 stored in a memory 1004 to process and/or generate circuit component 1020 responsive to user inputs 1014 and parameters 1016. Processes 1012 may be any suitable electronic design automation (EDA) tool or portion thereof used to design, simulate, analyze, and/or verify electronic circuitry and/or generate photomasks for electronic circuitry. Representation 1020 includes data that describes all or portions of memory system 100, module 200, data buffer circuitry 300, and their components, as shown in the Figures.

Representation 1020 may include one or more of behavioral, register transfer, logic component, transistor, and layout geometry-level descriptions. Moreover, representation 1020 may be stored on storage media or communicated by carrier waves.

Data formats in which representation 1020 may be implemented include, but are not limited to: formats supporting behavioral languages like C, formats supporting register transfer level (RTL) languages like Verilog and VHDL, formats supporting geometry description languages (such as GDSII, GDSIII, GDSIV, CIF, and MEBES), and other suitable formats and languages. Moreover, data transfers of such files on machine-readable media may be done electronically over the diverse media on the Internet or, for example, via email

User inputs 1014 may comprise input parameters from a keyboard, mouse, voice recognition interface, microphone and speakers, graphical display, touch screen, or other type of user interface device. This user interface may be distributed among multiple interface devices. Parameters 1016 may include specifications and/or characteristics that are input to help define representation 1020. For example, parameters 1016 may include information that defines device types (e.g., NFET, PFET, etc.), topology (e.g., block diagrams, circuit descriptions, schematics, etc.), and/or device descriptions (e.g., device properties, device dimensions, power supply voltages, simulation temperatures, simulation models, etc.).

Memory 1004 includes any suitable type, number, and/or configuration of non-transitory computer-readable storage media that stores processes 1012, user inputs 1014, parameters 1016, and circuit component 1020.

Communications devices 1006 include any suitable type, number, and/or configuration of wired and/or wireless devices that transmit information from processing system 1000 to another processing or storage system (not shown) and/or receive information from another processing or storage system (not shown). For example, communications devices 1006 may transmit circuit component 1020 to another system. Communications devices 1006 may receive processes 1012, user inputs 1014, parameters 1016, and/or circuit component 1020 and cause processes 1012, user inputs 1014, parameters 1016, and/or circuit component 1020 to be stored in memory 1004.

Implementations discussed herein include, but are not limited to, the following examples:
Example 1: A memory module, comprising: a first plurality of dynamic random access memory (DRAM) devices each having a respective first memory access interface and a second respective memory access interface to operate independently of each other to access one of two respective sets of memory cores in respective ones of the first plurality of DRAM devices where respective sets of memory cores in the respective ones of the first plurality of DRAM devices are non-overlapping sets; a first memory access channel interface to communicate data with each of the respective first memory access interfaces; a second memory access channel interface to communicate data with each of the respective second memory access interfaces; and a first plurality of data buffer devices each having a first host side interface, a first device side interface, a second host side interface, and a second device side interface, respective first host side interfaces and respective second host side interfaces each to operate independently of each other, respective first device side interfaces and respective second device side interfaces to each include more data strobe signals than respective first host side interfaces and respective second host side interface, each of the respective first device side interfaces and each of the respective second device side interfaces to communicate with at least two of the first plurality of DRAM devices.

Example 2: The memory module of example 1, further comprising: a second plurality of dynamic random access memory (DRAM) devices each having a respective third memory access interface and a fourth respective memory access interface to operate independently of each other to access one of two respective sets of memory cores in respective ones of the second plurality of DRAM devices where the respective sets of memory cores in the respective ones of the second plurality of DRAM devices are non-overlapping sets; a third memory access channel interface to communicate data with the respective third memory access interfaces; a fourth memory access channel interface to communicate data with the respective fourth memory access interfaces; and, a second plurality of data buffer devices each having a third host side interface, a third device side interface, a fourth host side interface, and a fourth device side interface, respective third host side interfaces and respective fourth host side interfaces each to operate independently of each other, respective third device side interfaces and respective fourth device side interfaces to each include more data strobe signals than respective third host side interfaces and respective fourth host side interfaces, each of the respective third device side interfaces and each of the respective fourth device side interfaces to communicate with at least two of the second plurality of DRAM devices.

Example 3: The memory module of example 1, wherein the first plurality of data buffer devices include first circuitry to determine a first timing between a first data strobe transmitted via the first device side interface and at least a first data signal transmitted via the first device side interface and second circuitry to, independent of the first timing, determine a second timing between a second data strobe transmitted via the second device side interface and at least a second data signal transmitted via the second device side interface.

Example 4: The memory module of example 1, wherein the first plurality of data buffer devices include first circuitry to determine a first timing between a first data strobe transmitted via the first device side interface to a first one of the at least two of the first plurality of DRAM devices and at least a first data signal transmitted via the first device side interface to the first one of the at least two of the first plurality of DRAM devices and second circuitry to, independent of the first timing, determine a second timing between a second data strobe transmitted via the second device side interface to a second one of the at least two of the first plurality of DRAM devices and at least a second data signal transmitted via the second device side interface to the second one of the at least two of the first plurality of DRAM devices.

Example 5: The memory module of example 1, wherein the first plurality of data buffer devices include first circuitry to determine a first timing between a first data strobe received via the first device side interface and a first sampling of at least a first data signal transmitted to the first device side interface and second circuitry to, independent of the first timing, determine a second timing between a second data strobe received via the second device side interface and a second sampling of at least a second data signal transmitted to the second device side interface.

Example 6: The memory module of example 1, wherein the first plurality of data buffer devices include first circuitry to determine a first timing between a first data strobe received via the first device side interface from a first one of the at least two of the first plurality of DRAM devices and a first sampling of at least a first data signal transmitted to the first device side interface from the first one of the at least two of the first plurality of DRAM devices and second circuitry to, independent of the first timing, determine a second timing between a second data strobe received via the second device side interface from a second one of the at least two of the first plurality of DRAM devices and a sampling of at least a second data signal transmitted to the second device side interface from the second one of the at least two of the first plurality of DRAM devices.

Example 7: A memory module, comprising: a first plurality of dual independent channel dynamic random access memory (DRAM) devices; and, a first plurality of dual independent channel data buffer devices each to communicate data with the first plurality of dual independent channel DRAM devices, each of the first plurality of dual independent channel data buffer devices to communicate data with a unique two of the first plurality of dual independent channel DRAM devices, each of the first plurality of dual independent channel data buffer devices to communicate the data with the unique two of the first plurality of dual independent channel DRAM devices using both dual independent channels of the unique two of the first plurality of dual independent channel DRAM devices and corresponding both dual independent channels of the first plurality of dual independent channel data buffer devices.

Example 8: The memory module of example 7, further comprising: a second plurality of dual independent channel DRAM devices; and, a second plurality of dual independent channel data buffer devices each to communicate data with the second plurality of dual independent channel DRAM devices, each of the second plurality of dual independent channel data buffer devices to communicate data with a unique two of the second plurality of dual independent channel DRAM devices, each of the second plurality of dual independent channel data buffer devices to communicate the data with the unique two of the second plurality of dual independent channel DRAM devices using both dual independent channels of the unique two of the second plurality of dual independent channel DRAM devices and corresponding both dual independent channels of the second plurality of dual independent channel data buffer devices, the first plurality of dual independent channel DRAM devices to be operated independently of the second plurality of dual independent channel DRAM devices.

Example 9: The memory module of example 8, wherein the first plurality of dual independent channel data buffer devices communicate a first data strobe with a first access interface of a first one of the unique two of the first plurality of dual independent channel DRAM devices, a second data strobe with the first access interface of a second one of the unique two of the first plurality of dual independent channel DRAM devices, a third data strobe with a second access interface of the first one of the unique two of the first plurality of dual independent channel DRAM devices, and a fourth data strobe with the second access interface of the second one of the unique two of the first plurality of dual independent channel DRAM devices.

Example 10: The memory module of example 9, wherein timings between data communicated between the unique two of the first plurality of dual independent channel DRAM devices and a corresponding one of the first plurality of dual independent channel data buffer devices and the first data strobe, the second data strobe, the third data strobe, and the fourth data strobe of the corresponding one of the first plurality of dual independent channel data buffer devices are to be independently set.

Example 11: The memory module of example 9, further comprising: a registering clock driver device having a first command interface to transmit commands to respective first independent channels of the first plurality of dual independent channel DRAM devices, a second command interface to transmit commands to respective second independent channels of the first plurality of dual independent channel DRAM devices, a third command interface to transmit commands to respective first independent channels of the second plurality of dual independent channel DRAM devices, and a fourth command interface to transmit commands to respective second independent channels of the second plurality of dual independent channel DRAM devices.

Example 12: The memory module of example 11, wherein the registering clock driver device further comprises: a first host command interface to receive commands to transmit to respective first independent channels of the first plurality of dual independent channel DRAM devices, a second host command interface to receive commands to transmit to respective second independent channels of the first plurality of dual independent channel DRAM devices, a third host command interface to receive commands to transmit to respective first independent channels of the second plurality of dual independent channel DRAM devices, and a fourth host command interface to receive commands to transmit to respective second independent channels of the second plurality of dual independent channel DRAM devices.

Example 13: The memory module of example 12, wherein the first command interface transmits commands via a first number of signal connections, the first host command interface receives commands via a second number of signal connections, where the first number of signal connections is substantially double the second number of signal connections.

Example 14: The memory module of example 11, wherein the registering clock driver device further comprises: a first host command interface to receive commands to transmit to respective first independent channels of the first plurality of dual independent channel DRAM devices and to receive commands to transmit to respective second independent channels of the first plurality of dual independent channel DRAM devices, a second host command interface to receive commands to transmit to respective first independent channels of the second plurality of dual independent channel DRAM devices and to receive commands to transmit to respective second independent channels of the second plurality of dual independent channel DRAM devices.

Example 15: The memory module of example 14, wherein the commands to be transmitted to the respective first independent channels of the first plurality of dual independent channel DRAM devices and to be transmitted to the respective second independent channels of the first plurality of dual independent channel DRAM devices are time-multiplexed.

Example 16: A memory module, comprising: a plurality of dynamic random access memory (DRAM) devices, each of the plurality of DRAM devices comprising a first memory device access interface and a second memory device access interface that each include command, address, and data transfer function that operate independently of the command, address, and data transfer function of the other of the first memory device access interface and the second memory device access interface; a plurality of data buffer devices, each of the plurality of data buffer devices comprising a first DRAM device data interface and a second DRAM device data interface; respective ones of the first DRAM device data interfaces of the plurality of data buffer devices to communicate data with a respective unique subset of two of the plurality of DRAM devices via respective ones of the first memory device access interface of the respective unique subset of two of the plurality of DRAM devices, the data communicated with the respective unique subset of two of the plurality of DRAM devices via respective ones of the first memory device access interface of the respective unique subset of two of the plurality of DRAM devices to also be communicated via a one of a first memory channel and a second memory channel; respective ones of the second DRAM device data interfaces of the plurality of data buffer devices to communicate data with the respective unique subset of two of the plurality of DRAM devices via respective ones of the second memory device access interface of the respective unique subset of two of the plurality of DRAM devices, the data communicated with the respective unique subset of two of the plurality of DRAM devices via respective ones of the second memory device access interface of the respective unique subset of two of the plurality of DRAM devices to also be communicated via a one of a third memory channel and a fourth memory channel; and, the first memory channel, the second memory channel, the third memory channel, and the fourth memory channel each including command, address, and data transfer functions that operate independently of the command, address, and data transfer function of the other of the first memory channel, the second memory channel, the third memory channel, and the fourth memory channel.

Example 17: The memory module of example 16, wherein the first DRAM device data interface includes a first data strobe signal and a second data strobe signal.

Example 18: The memory module of example 17, wherein each respective first data strobe signal determines a first respective timing of the data communicated with a respective first one of the respective unique subset of two of the plurality of DRAM devices and each respective second data strobe signal determines a second respective timing of the data communicated with a respective second one of the respective unique subset of two of the plurality of DRAM devices.

Example 19: The memory module of example 16, wherein the first memory channel communicates data with a first subset of the plurality of DRAM devices via respective first memory device access interfaces.

Example 20: The memory module of example 18, wherein the first memory channel includes a first number of memory channel data strobe signals and respective first memory device access interfaces include a second number of memory device access interface data strobe signals, where the second number is at least twice the first number.

The foregoing description of the invention has been presented for purposes of illustration and description. It is not intended to be exhaustive or to limit the invention to the precise form disclosed, and other modifications and variations may be possible in light of the above teachings. The embodiment was chosen and described in order to best explain the principles of the invention and its practical application to thereby enable others skilled in the art to best utilize the invention in various embodiments and various modifications as are suited to the particular use contemplated. It is intended that the appended claims be construed to include other alternative embodiments of the invention except insofar as limited by the prior art.

What is claimed is:

1. A memory module, comprising:
a first plurality of dynamic random access memory (DRAM) devices each having a respective first memory access interface and a second respective memory access interface to operate independently of each other to access one of two respective sets of memory cores in respective ones of the first plurality of DRAM devices where respective sets of memory cores in the respective ones of the first plurality of DRAM devices are non-overlapping sets;
a first memory access channel interface to communicate data with each of the respective first memory access interfaces;
a second memory access channel interface to communicate data with each of the respective second memory access interfaces; and
a first plurality of data buffer devices each having a first host side interface, a first device side interface, a second host side interface, and a second device side interface, respective first host side interfaces and respective second host side interfaces each to operate independently of each other, respective first device side interfaces and respective second device side interfaces to each include more data strobe signals than respective first host side interfaces and respective second host side interface, each of the respective first device side interfaces and each of the respective second device side interfaces to communicate with at least two of the first plurality of DRAM devices.

2. The memory module of claim 1, further comprising:
a second plurality of dynamic random access memory (DRAM) devices each having a respective third memory access interface and a fourth respective memory access interface to operate independently of each other to access one of two respective sets of memory cores in respective ones of the second plurality of DRAM devices where the respective sets of memory cores in the respective ones of the second plurality of DRAM devices are non-overlapping sets;
a third memory access channel interface to communicate data with the respective third memory access interfaces;
a fourth memory access channel interface to communicate data with the respective fourth memory access interfaces; and
a second plurality of data buffer devices each having a third host side interface, a third device side interface, a fourth host side interface, and a fourth device side interface, respective third host side interfaces and respective fourth host side interfaces each to operate independently of each other, respective third device side interfaces and respective fourth device side interfaces to each include more data strobe signals than respective third host side interfaces and respective fourth host side interfaces, each of the respective third device side interfaces and each of the respective fourth device side interfaces to communicate with at least two of the second plurality of DRAM devices.

3. The memory module of claim 1, wherein the first plurality of data buffer devices include first circuitry to determine a first timing between a first data strobe transmitted via the first device side interface and at least a first data signal transmitted via the first device side interface and second circuitry to, independent of the first timing, determine a second timing between a second data strobe transmitted via the second device side interface and at least a second data signal transmitted via the second device side interface.

4. The memory module of claim 1, wherein the first plurality of data buffer devices include first circuitry to determine a first timing between a first data strobe transmitted via the first device side interface to a first one of the at least two of the first plurality of DRAM devices and at least a first data signal transmitted via the first device side interface to the first one of the at least two of the first plurality of DRAM devices and second circuitry to, independent of the first timing, determine a second timing between a second data strobe transmitted via the second device side interface to a second one of the at least two of the first plurality of DRAM devices and at least a second data signal transmitted via the second device side interface to the second one of the at least two of the first plurality of DRAM devices.

5. The memory module of claim 1, wherein the first plurality of data buffer devices include first circuitry to determine a first timing between a first data strobe received via the first device side interface and a first sampling of at least a first data signal transmitted to the first device side interface and second circuitry to, independent of the first timing, determine a second timing between a second data strobe received via the second device side interface and a second sampling of at least a second data signal transmitted to the second device side interface.

6. The memory module of claim 1, wherein the first plurality of data buffer devices include first circuitry to determine a first timing between a first data strobe received via the first device side interface from a first one of the at least two of the first plurality of DRAM devices and a first sampling of at least a first data signal transmitted to the first device side interface from the first one of the at least two of the first plurality of DRAM devices and second circuitry to, independent of the first timing, determine a second timing between a second data strobe received via the second device side interface from a second one of the at least two of the first plurality of DRAM devices and a sampling of at least a second data signal transmitted to the second device side interface from the second one of the at least two of the first plurality of DRAM devices.

7. A memory module, comprising:
a first plurality of dual independent channel dynamic random access memory (DRAM) devices; and
a first plurality of dual independent channel data buffer devices each to communicate data with the first plurality of dual independent channel DRAM devices, each of the first plurality of dual independent channel data buffer devices to communicate data with a unique two of the first plurality of dual independent channel DRAM devices, each of the first plurality of dual independent channel data buffer devices to communicate the data with the unique two of the first plurality of dual independent channel DRAM devices using both dual independent channels of the unique two of the first plurality of dual independent channel DRAM devices and corresponding both dual independent channels of the first plurality of dual independent channel data buffer devices.

8. The memory module of claim 7, further comprising:
a second plurality of dual independent channel DRAM devices; and
a second plurality of dual independent channel data buffer devices each to communicate data with the second plurality of dual independent channel DRAM devices, each of the second plurality of dual independent channel data buffer devices to communicate data with a unique two of the second plurality of dual independent channel DRAM devices, each of the second plurality of dual independent channel data buffer devices to communicate the data with the unique two of the second plurality of dual independent channel DRAM devices using both dual independent channels of the unique two of the second plurality of dual independent channel DRAM devices and corresponding both dual independent channels of the second plurality of dual independent channel data buffer devices, the first plurality of dual independent channel DRAM devices to be operated independently of the second plurality of dual independent channel DRAM devices.

9. The memory module of claim 8, wherein the first plurality of dual independent channel data buffer devices communicate a first data strobe with a first access interface of a first one of the unique two of the first plurality of dual independent channel DRAM devices, a second data strobe with the first access interface of a second one of the unique two of the first plurality of dual independent channel DRAM devices, a third data strobe with a second access interface of the first one of the unique two of the first plurality of dual independent channel DRAM devices, and a fourth data strobe with the second access interface of the second one of the unique two of the first plurality of dual independent channel DRAM devices.

10. The memory module of claim 9, wherein timings between data communicated between the unique two of the first plurality of dual independent channel DRAM devices and a corresponding one of the first plurality of dual independent channel data buffer devices and the first data strobe, the second data strobe, the third data strobe, and the fourth data strobe of the corresponding one of the first plurality of dual independent channel data buffer devices are to be independently set.

11. The memory module of claim 9, further comprising:
a registering clock driver device having a first command interface to transmit commands to respective first independent channels of the first plurality of dual independent channel DRAM devices, a second command interface to transmit commands to respective second independent channels of the first plurality of dual independent channel DRAM devices, a third command interface to transmit commands to respective first independent channels of the second plurality of dual independent channel DRAM devices, and a fourth command interface to transmit commands to respective second independent channels of the second plurality of dual independent channel DRAM devices.

12. The memory module of claim 11, wherein the registering clock driver device further comprises:
a first host command interface to receive commands to transmit to respective first independent channels of the first plurality of dual independent channel DRAM devices, a second host command interface to receive commands to transmit to respective second independent channels of the first plurality of dual independent channel DRAM devices, a third host command interface to receive commands to transmit to respective first independent channels of the second plurality of dual independent channel DRAM devices, and a fourth host command interface to receive commands to transmit to respective second independent channels of the second plurality of dual independent channel DRAM devices.

13. The memory module of claim 12, wherein the first command interface transmits commands via a first number of signal connections, the first host command interface receives commands via a second number of signal connections, where the first number of signal connections is substantially double the second number of signal connections.

14. The memory module of claim 11, wherein the registering clock driver device further comprises:
a first host command interface to receive commands to transmit to respective first independent channels of the first plurality of dual independent channel DRAM devices and to receive commands to transmit to respective second independent channels of the first plurality of dual independent channel DRAM devices, a second host command interface to receive commands to transmit to respective first independent channels of the second plurality of dual independent channel DRAM devices and to receive commands to transmit to respective second independent channels of the second plurality of dual independent channel DRAM devices.

15. The memory module of claim 14, wherein the commands to be transmitted to the respective first independent channels of the first plurality of dual independent channel DRAM devices and to be transmitted to the respective second independent channels of the first plurality of dual independent channel DRAM devices are time-multiplexed.

16. A memory module, comprising:
a plurality of dynamic random access memory (DRAM) devices, each of the plurality of DRAM devices comprising a first memory device access interface and a second memory device access interface that each include command, address, and data transfer function that operate independently of the command, address, and data transfer function of the other of the first memory device access interface and the second memory device access interface;
a plurality of data buffer devices, each of the plurality of data buffer devices comprising a first DRAM device data interface and a second DRAM device data interface;
respective ones of the first DRAM device data interfaces of the plurality of data buffer devices to communicate data with a respective unique subset of two of the plurality of DRAM devices via respective ones of the first memory device access interface of the respective unique subset of two of the plurality of DRAM devices, the data communicated with the respective unique subset of two of the plurality of DRAM devices via respective ones of the first memory device access interface of the respective unique subset of two of the plurality of DRAM devices to also be communicated via a one of a first memory channel and a second memory channel;
respective ones of the second DRAM device data interfaces of the plurality of data buffer devices to communicate data with the respective unique subset of two of the plurality of DRAM devices via respective ones of the second memory device access interface of the respective unique subset of two of the plurality of DRAM devices, the data communicated with the respective unique subset of two of the plurality of DRAM devices via respective ones of the second memory device access interface of the respective unique subset of two of the plurality of DRAM devices to also be communicated via a one of a third memory channel and a fourth memory channel; and
the first memory channel, the second memory channel, the third memory channel, and the fourth memory channel each including command, address, and data transfer functions that operate independently of the command, address, and data transfer function of the other of the first memory channel, the second memory channel, the third memory channel, and the fourth memory channel.

17. The memory module of claim 16, wherein the first DRAM device data interface includes a first data strobe signal and a second data strobe signal.

18. The memory module of claim 17, wherein each respective first data strobe signal determines a first respective timing of the data communicated with a respective first one of the respective unique subset of two of the plurality of DRAM devices and each respective second data strobe signal determines a second respective timing of the data communicated with a respective second one of the respective unique subset of two of the plurality of DRAM devices.

19. The memory module of claim 16, wherein the first memory channel communicates data with a first subset of the plurality of DRAM devices via respective first memory device access interfaces.

20. The memory module of claim 18, wherein the first memory channel includes a first number of memory channel data strobe signals and respective first memory device access interfaces include a second number of memory device access interface data strobe signals, where the second number is at least twice the first number.
